(19) United States
(12) Patent Application Publication
(10) Pub. No.: US 2016/0344162 A1
(43) Pub. Date: Nov. 24, 2016

(54) BEAM COMBINING DEVICE AND OUTPUT RECOVERY METHOD FOR BEAM COMBINING DEVICE

(71) Applicant: MITSUBISHI ELECTRIC CORPORATION, Tokyo (JP)

(72) Inventors: Susumu KONNO, Chiyoda-ku (JP); Masato KAWASAKI, Chiyoda-ku (JP); Daiji MORITA, Chiyoda-ku (JP); Tomotaka KATSURA, Chiyoda-ku (JP); Shuichi FUJIKAWA, Chiyoda-ku (JP)

(73) Assignee: MITSUBISHI ELECTRIC CORPORATION, Tokyo (JP)

(21) Appl. No.: 15/112,598

(22) PCT Filed: Jan. 22, 2015
(86) PCT No.: PCT/JP2015/051663

§ 371 Date: Jul. 19, 2016

(30) Foreign Application Priority Data
Jan. 30, 2014 (JP) 2014-015840

(51) Int. Cl. H01S 5/40; H01S 3/08; H01S 5/0683; H01S 5/14

(52) U.S. Cl. CPC H01S 5/4012; H01S 5/14; H01S 5/4025; H01S 3/08059; H01S 5/143; H01S 5/0683

(57) ABSTRACT

A beam combining device causing beams from a plurality of light sources and one or a plurality of spare light sources to enter a beam combining optical system, and to be combined and output after passing through a beam combining element. The beam combining device is configured to: detect a failure in the plurality of light sources; and move at least a part of the respective light sources, the spare light source, and the beam combining optical system, to cause a beam to enter the beam combining optical system from the spare light source instead of a beam from the failed light source, and to cause the beam to be combined to beams from the plurality of light sources on an optical path after the beam combining element.

### TECHNICAL FIELD

The present invention relates to a beam combining device configured to combine a plurality of laser light beams into one light flux and use the light flux and an output recovery method for the beam combining device, in particular, to redundancy using a spare light source (recovery function to be enabled at a time of failure in a light source) or the like.

### BACKGROUND ART

For example, a related-art beam combining device of this kind, which is disclosed in PTL 1, has a configuration for combining a plurality of laser beams, in which optical fibers are respectively fixed to a plurality of laser light emitting unit that are provided, and those optical fibers are bundled to form a handle portion for the optical fibers.

### CITATION LIST

### Patent Literature

[PTL 1] JP 5270949 B2 (page 4, line 50 to page 5, line 8 and FIG. 1 to FIG. 5)

### SUMMARY OF INVENTION

### Technical Problem

Such a related-art beam combining device exhibits no degree of freedom when a plurality of laser beams are combined because each optical fiber is fixed to each laser light emitting unit. Therefore, for example, when a spare laser light emitting unit to be used at a time of failure is provided, there is a limitation on the number of beams that can be combined, and hence the spare laser light emitting unit occupies a part of the number of beams to be combined, which lowers an upper limit of a laser output.

The present invention has been made in order to solve the above-mentioned problem, and has an object to obtain a beam combining device and the like, which have the structure having a degree of freedom of combining a plurality of laser beams, and which are capable of adding a spare light source without lowering an upper limit of a laser output.

### Solution to Problem

According to one embodiment of the present invention, there are provided a beam combining device and the like, including: a plurality of light sources; one or a plurality of spare light sources; a beam combining optical system configured to cause a beam combining element to combine beams from the respective light sources and the spare light source and to output the combined beams so that the beams having entered the beam combining optical system from the respective light sources and the spare light source are combined after passing through the beam combining element; a monitoring unit configured to monitor the beams from the respective light sources in order to detect a failure; and a light source switching unit configured to: move, when a failure in the light source is detected, at least a part of the respective light sources, the spare light source, and the beam combining optical system by a movable unit provided to at least a part of the respective light sources, the spare light source, and the beam combining optical system; cause a beam to enter the beam combining optical system from the spare light source instead of a beam from the failed light source; and cause the beam to be combined to beams from the plurality of light sources on an optical path after the beam combining element.

### Advantageous Effects of Invention

According to the present invention, the beam combining device and the like, which have the structure having the degree of freedom of combining the plurality of laser beams, and which are capable of adding the spare light source without lowering the upper limit of the laser output, can be provided.

### BRIEF DESCRIPTION OF DRAWINGS

FIG. 1 is a schematic block diagram of a beam combining device according to a first embodiment of the present invention.

FIG. 2 is a diagram for illustrating an operation of the beam combining device according to the first embodiment of the present invention.

FIG. 3 is a schematic block diagram of a beam combining device according to a second embodiment of the present invention.

FIG. 4 is a side surface view of LD packages of FIG. 3.

FIG. 5 is a schematic block diagram of a beam combining device according to a third embodiment of the present invention.

FIG. 6 is a diagram for illustrating an operation of the beam combining device according to the third embodiment of the present invention.

FIG. 7 is a schematic block diagram of a beam combining device according to a fourth embodiment of the present invention.

FIG. 8 is a diagram for illustrating spatial combining (positional combining) conducted by a beam combining device according to the fourth embodiment of the present invention.

FIG. 9 is a diagram for illustrating polarization beam combining conducted by the beam combining device according to the fourth embodiment of the present invention.

FIG. 10 is a diagram for illustrating wavelength beam combining conducted by the beam combining device according to the fourth embodiment of the present invention.

FIG. 11 is a diagram for illustrating an operation conducted by the beam combining device when a module is stopped according to the fourth embodiment of the present invention.

FIG. 12 is a schematic block diagram of a beam combining device according to a fifth embodiment of the present invention.

FIG. 13 is a diagram for illustrating an example of a configuration of a laser module of the beam combining device according to the fifth embodiment of the present invention, the laser module not having a spare light source mounted thereon.

FIG. 14 is a diagram for illustrating a circuit configuration of the laser module of the beam combining device according to the fifth embodiment of the present invention, which is obtained at a time of failure in a light source, the laser module not having a spare light source mounted thereon.

FIG. 15 is a schematic block diagram of a beam combining device according to a seventh embodiment of the present invention.

FIG. 16 is a diagram for illustrating another configuration example of a wiring switching box of the beam combining device according to the third embodiment of the present invention.

FIG. 17 is a schematic block diagram of a beam combining device according to an eighth embodiment of the present invention.

FIG. 18 is a diagram for illustrating an operation of the beam combining device according to the eighth embodiment of the present invention.

FIG. 19 is a diagram for illustrating an operation of the beam combining device according to the eighth embodiment of the present invention.

FIG. 20 is a diagram for illustrating an operation of the beam combining device according to the eighth embodiment of the present invention.

FIG. 21 is a table for showing control of folding mirrors for a failure in each LD package of the beam combining device according to the eighth embodiment of the present invention.

### DESCRIPTION OF EMBODIMENTS

Now, a beam combining device and the like according to each of embodiments of the present invention are described with reference to the drawings. In each of the embodiments, the same or corresponding portions are denoted by the same or corresponding reference symbols, and the overlapping description thereof is omitted.

### First Embodiment

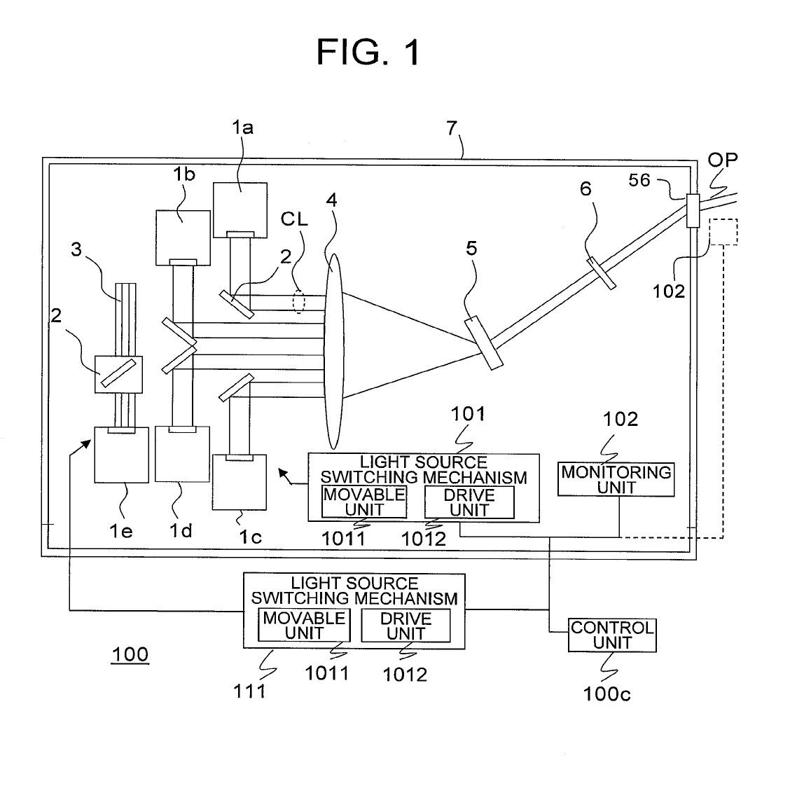

FIG. 1 is a schematic block diagram of a beam combining device according to a first embodiment of the present invention. A beam combining device 100 including a wavelength beam combining external resonator combines light beams from a laser diode (LD) element serving as a light source into one beam based on a dispersive property, and outputs the one beam. A brief description is made of an operation mechanism with reference to FIG. 1. Laser beams emitted from LD packages 1a to 1e each serving as a light source having an LD bar mounted thereon have directions thereof changed by folding mirrors 2 (optical elements each configured to change a beam direction on an optical path) provided to the respective LD packages 1a to 1e on a one-to-one basis, and are emitted onto a cylindrical lens 4. The laser beams are superimposed at a diffraction grating 5 serving as a beam combining element by the cylindrical lens 4, and are superimposed into one beam between the diffraction grating 5 and a partially transmitting mirror 6 based on the dispersive property of the diffraction grating 5. There is provided a casing 7 configured to store the LD packages 1a to 1e, the respective folding mirrors 2, a rail 3 described later, the cylindrical lens 4, the diffraction grating 5, and the partially transmitting mirror 6. In order to extract a beam from the casing 7, there is arranged an output transmitting element 56 or the like having functions of a beam transmitting element and a dispersive optical element. In FIG. 1, the LD package 1e is a spare light source, and an LD package equivalent to the other LD packages is mounted. Further, as exemplified by the broken line, a collimator lens CL is appropriately provided as the need arises (the same applies below).

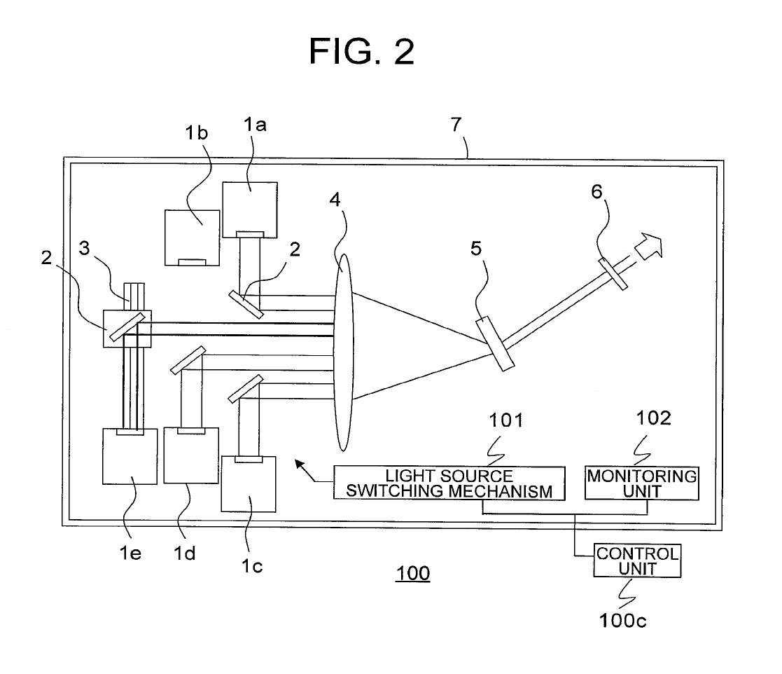

FIG. 2 is an illustration of how the spare LD package 1e operates in the configuration of FIG. 1 when the LD package 1b fails. The folding mirror 2 placed on a laser beam output side of the LD package 1b is removed or moved to an outside of the optical path of the laser beam from the LD package 1b, and instead, the folding mirror 2 for the spare LD package 1e is moved on the rail 3 and arranged so that the optical path coincides with a position in which there was an optical path of the LD package 1b. The folding mirror 2 is arranged with sufficient arrangement accuracy enough to enable the functioning as a substitute of the LD package 1b. The rail 3 is offset (for example, offset toward the back surface of the drawing sheet of the figure) from the optical path so as not to block the laser beam.

The rail 3 may be provided to each of the LD packages 1a to 1e, and the folding mirror 2 may be moved individually. Further, there is provided a mechanism that enables the folding mirror 2 for the LD package 1e, the folding mirror 2 for the LD package 1b, and the folding mirror and others for the other LD packages to be moved manually or electrically from the outside of the casing 7, and the movement can be conducted without the opening of the casing 7. Further, it is desired that such a monitor mechanism (monitoring unit 102) as illustrated in FIG. 1 be provided, the monitor mechanism enabling output reduction of the LD packages 1a to 1e to be individually monitored inside or outside the casing 7 at any time. In FIG. 2 and the subsequent figures, the components provided outside the casing 7 are omitted from the illustrations.

Specifically, the respective LD packages 1a to 1e are subjected to the adjustment and on/off of power supply from a power supply circuit. Further, the respective LD packages 1a to 1e each include a drive motor (not shown) configured to move the folding mirror 2 onto the rail 3. A light source switching function for those is illustrated as a light source switching mechanism 101. Further, a monitor device for a state of an LD package (configured to monitor a wavelength of a laser beam output from the LD package, an intensity (output) of a laser beam, an emission direction, a voltage at an LD of the LD package, and the like), for detecting a failure of the LD packages 1a to 1e, is illustrated as the monitoring unit 102. A control unit 100c formed of a computer or the like provided outside the casing 7 is connected to the light source switching mechanism 101 and the monitoring unit 102, and controls the light source switching mechanism 101 to control the on/off of the LD package (specifically, connection to and disconnection from the power supply circuit based on the on/off of power supply from the power supply circuit), the adjustment of the power supply, and the movement of the folding mirror 2 based on an input from an operator. Further, the control unit 100c determines a failed LD package based on the state of the LD package monitored by the monitoring unit 102.

The control unit 100c may be configured to determine the failed LD package based on the state of the LD package obtained from the monitoring unit 102, and to control the light source switching mechanism 101 based on a determination result to disconnect the failed LD package from the power supply circuit while connecting a spare LD package to the power supply circuit instead, and to further disconnect the folding mirror for the failed LD package from the optical path while moving the folding mirror for the spare LD package so that the optical path is superimposed on the optical path of the failed LD package.

Further, when the folding mirror 2 is manually moved, an operation rod having one end combined to the folding mirror 2 and the other end projecting outward through the casing 7 is manually operated by the operator.

With the beam combining device configured in the above-mentioned manner, it is possible to start the operation of a spare LD package instead of the LD package in which a failure has occurred without opening the casing 7.

The description of this embodiment is directed to the case where the LD bar is mounted to the LD package, but an LD chip may be a single chip.

Further, with respect to the number of LD packages, the description is directed to the case where four LD packages operate at startup with one spare LD package, but the numbers of LD packages and spare LD packages are not limited thereto. For example, a plurality of spare LD packages may be provided.

Further, in this embodiment, the diffraction grating 5 of a transmissive type is used as a dispersive medium (wavelength beam combining external resonator), but a device of the same kind (beam combining external resonator) can be configured in the case of any one of beam combining methods, such as wavelength beam combining, polarization beam combining, and spatial combining (positional combining).

Further, in a case where the light sources are combined into an optical fiber OP illustrated in FIG. 1 on an output side of the beam combining device, even when a difference occurs between the light from the LD package 1b and the light from the LD package 1e due to an optical path difference or the like, the influence of fluctuations in the beam due to the switching to a spare LD can be alleviated to some extent by an symmetrization effect of a beam mode based on the fiber propagation.

According to this embodiment, when a normal operation can no longer be conducted due to the lowering of an optical output from the LD package or other such causes, the normal operation can be continued by a spare LD package arranged within the casing starting an operation thereof. Further, during the normal operation, the spare LD package occupies none of optical paths of a wavelength beam combining external oscillator, and hence the limit of an output during the normal operation is not to be lowered due to the existence of the spare LD package. This produces an effect of, when the same number of LD packages are used, maintaining redundancy in that an alternative operation can be conducted using a spare LD package at a time of LD failure while ensuring the redundancy by leaving the optical path unoccupied without thereby lowering the limit of the output. Further, a device configured to automatically measure which LD package has failed is provided, to thereby be able to conduct the alternative operation without opening the casing. Therefore, it is possible to conduct such replacement as to avoid the influence of contamination or moisture.

In the light source switching mechanism 101 of FIG. 1, a movable unit 1101 for conducting the above-mentioned operation and a drive unit 1102 configured to drive the movable unit 1101 are schematically illustrated.

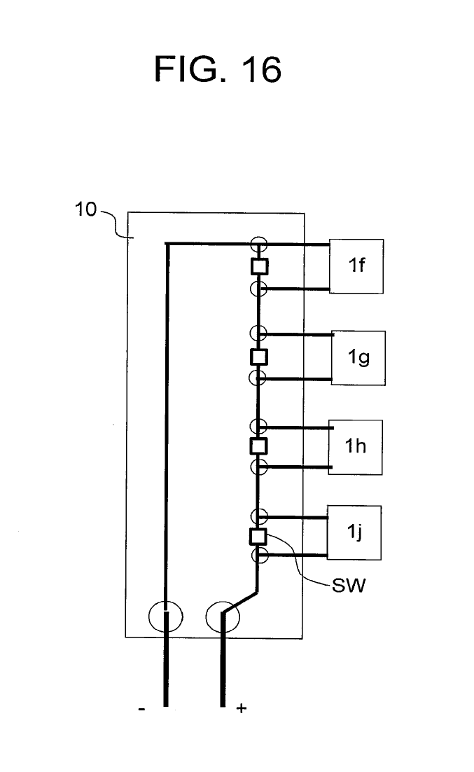

For example, the movable unit 1101 includes a mechanism for moving the folding mirror 2 onto the rail 3, and further includes, as illustrated in, for example, FIG. 16, an electric switch having a mechanism for conducting the adjustment and on/off control of the power supply from the power supply circuit to the respective LD packages 1a to 1e.

The drive unit 1102 includes, for example, a drive motor for driving the above-mentioned movable unit, a power supply circuit for the LD package, and a power source for those.

As those specific components, suitable components may be selected and provided depending on the use form (the same applies below).

A part of the light source switching mechanism 101 may be preferably provided outside the casing 7 as described later, and is illustrated as a light source switching mechanism 111.

In FIG. 2 and the subsequent figures, those are omitted from the illustrations.

### Second Embodiment

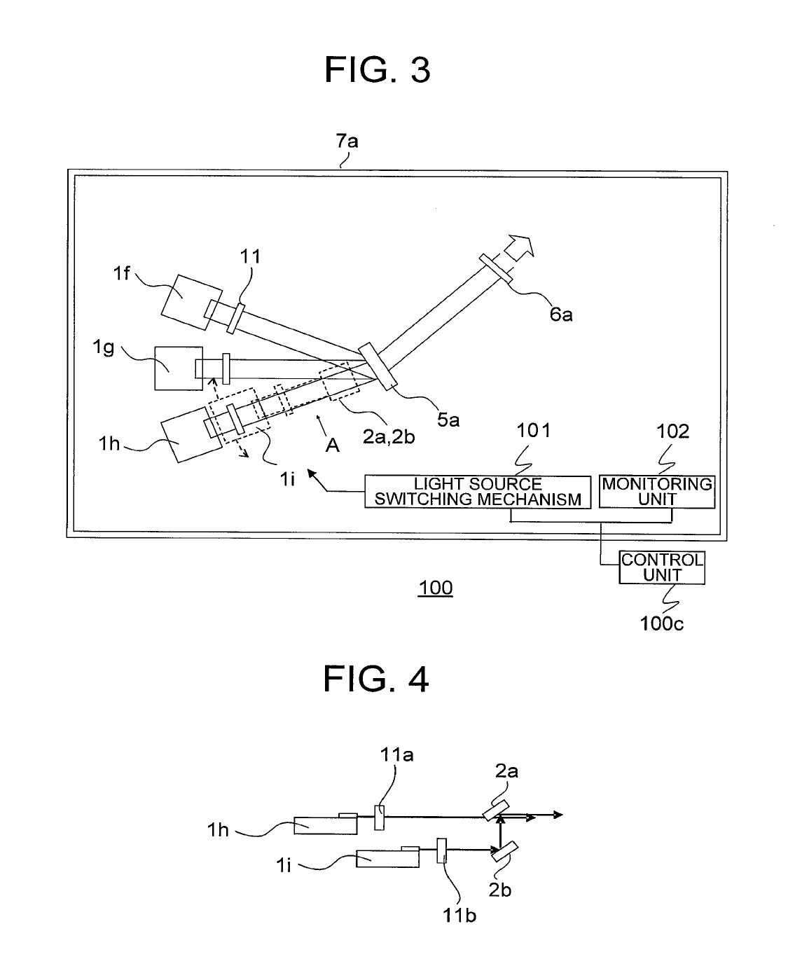

FIG. 3 is a schematic block diagram of a beam combining device according to a second embodiment of the present invention. As illustrated in FIG. 3, a mobile spare LD package may be provided to allow the switching of the optical path and to form a beam combining device having high redundancy. In FIG. 3, laser beams generated from LD packages 1f, 1g, and 1h are collimated by cylindrical lenses 11, and are superimposed at a diffraction grating 5a. The beams are superimposed between the diffraction grating 5a and a partially transmitting mirror 6a, and form different optical paths between the diffraction grating 5a and the LD packages 1f, 1g, and 1h. The beams from the different LD packages have different wavelengths and are diffracted at different angles due to the dispersive property exhibited by the diffraction grating 5a, and are therefore extracted as one beam from the partially transmitting mirror 6a.

FIG. 4 is an illustration of the LD package 1h viewed from the side surface in the direction indicated by the arrow A of FIG. 3. In this embodiment, a spare LD package 1i provided on the lower side (back surface side of the drawing sheet of FIG. 3) of the LD packages 1f, 1g, and 1h is configured to raise an optical path thereof (displace the optical path upward in parallel) through the movement of movable mirrors 2a and 2b at a time of failure in the LD package so as to allow the optical path to be superimposed on an optical path from the LD package 1h to the diffraction photon 5a. Further, as indicated by the dotted arrow in FIG. 3, the LD package 1i and the movable mirrors 2a and 2b therefor are configured to be able to move toward a direction of rotation about the diffraction grating 5a so as to allow the optical path to be superimposed on the optical path of not only the LD package 1h but also optical paths of the LD packages 1f and 1g at a time of failure.

With the beam combining device configured in the above-mentioned manner, whichever of the LD packages 1f, 1g, and 1h fails, the LD package 1i, a cylindrical lens 11b therefor, and the movable mirrors 2a and 2b for the raising (parallel displacement of the optical path) are rotated and raised, to thereby replace the optical path of a failed LD package, and it is possible to start the operation of the spare LD package instead of the failed package.

Although not shown in detail in this embodiment, it is desired that, in the same manner as in the above-mentioned embodiment, for example, the control unit 100c, the light source switching mechanisms 101 and 111, and the monitoring unit 102 be provided to determine which of the LD packages 1f, 1g, and 1h has failed and to replace the failed LD package by the spare LD package 1i. The monitoring unit 102 of the failed LD package is a wavelength beam combining resonator, and hence a device configured to monitor a wavelength may be mounted, or a fiber terminal capable of coupling the existing wavelength measuring device only at a time of monitoring may be provided in order to cut the cost of a wavelength measuring device.

Further, the voltage of each LD package may be monitored. In addition, when the diffraction grating 5a from which zero-order light of the diffraction grating 5a leaks is used, the direction of leakage light may be monitored to detect which LD package has failed.

Further, it is desired that a monitoring unit automatically operate or the monitoring unit be provided outside the casing 7a, and that a mechanism for moving the movable unit and a mechanism for switching wirings so as to inhibit a current from flowing into the failed LD package and to cause a current to flow into the spare LD package be further provided outside the casing, to thereby enable the switching without the opening of the casing.

In this case, for example, the light source switching mechanism 101 moves the LD package 1i, the cylindrical lens 11b therefor, and the movable mirrors 2a and 2b for the raising (parallel displacement of the optical path) in the direction of rotation about the diffraction grating 5a, and raises the movable mirrors 2a and 2b. The LD package 1i, the cylindrical lens 11b, and the movable mirrors 2a and 2b are provided, for example, on movable support portions (not shown) each including a drive motor for causing the above-mentioned operation to be conducted, and the light source switching mechanism 101 controls the movable support portion to move. Further, in the same manner as in the above-mentioned embodiment, the adjustment and on/off of the power supply to each LD package are conducted. The monitoring unit 102 monitors the states of the LD packages 1f, 1g, and 1h. The control unit 100c determines the failed LD package based on a monitoring result of the state of the LD package obtained from the monitoring unit 102, and controls the light source switching mechanism 101 based on the determination result to disconnect the failed LD package (for example, 1h) from the power supply circuit while connecting the spare LD package 1i to the power supply circuit instead, and further rotates the LD package 1i, the cylindrical lens 11b therefor, and the movable mirrors 2a and 2b up to positions below the failed LD package and raises the movable mirrors 2a and 2b.

The detection result of the state of the LD package obtained from the monitoring unit 102 may be displayed on a display unit (not shown) of the control unit 100c, and the operator may determine the failed LD package based on the display and input to the control unit 100c an instruction to switch from the failed LD package to the spare LD package. Then, the light source switching mechanism 101 may conduct the above-mentioned switching operation in response to a control signal from the control unit 100c that is based on the input instruction.

Further, the monitoring unit 102 may be provided outside the casing 7a, and configured to receive, in a position outside the casing 7a, a detection signal from a sensor (not shown) configured to detect a wavelength of a laser beam within the casing, the intensity (output) of the laser beam, the emission direction, the voltage at the LD of the LD package, and the like. In another case, the casing 7a may be formed to be partially transparent, and the state of the laser beam that can be detected from a separate place may be monitored from the outside of the casing 7a. Further, in regard to the light source switching mechanism 101, as described also in the subsequent embodiments, wiring switching may be conducted between the connection and the disconnection of the LD package to/from the power supply circuit by providing a wiring switching box configured to conduct the wiring switching outside the casing 7a and conducting the on/off control manually or under the control signal from the control unit 100c with an electric switch provided to the wiring switching box. The same applies to the other embodiments.

With the beam combining device configured in the above-mentioned manner, at a time of failure in the LD package, the failed LD package can be replaced by the spare LD package, and hence it is possible to generate a larger output without the need to reserve the optical path for the spare LD package in advance. Further, at a time of the replacement, the operation can be conducted from the outside of the casing after the detection of a failed part, which can alleviate the influence of the failure due to contamination. Further, it is possible to reduce time and labor to be required for the replacement.

The LD packages 1f, 1 g, and 1h being a plurality of light sources are arranged, for example, in a shape of a concentric circle about the diffraction grating 5a serving as the beam combining element. The LD package 1i serving as the spare light source moves along a trajectory exhibiting a concentric circle shape that has a radius smaller than those of the LD packages 1f, 1 g, and 1h and is offset toward a direction perpendicular to a plane including the concentric circle.

For example, the movable unit of the light source switching mechanism 101 includes the movable support portions configured to movably support the LD package 1i, the cylindrical lens 11b, and the movable mirrors 2a and 2b as described above, and further includes, as illustrated in, for example, FIG. 16, an electric switch SW having a mechanism for conducting the adjustment and on/off control of the power supply from the power supply circuit to the LD package. The drive unit includes the drive motor configured to operate the movable unit for those, the power supply circuit for the LD package, and the power source for those.

### Third Embodiment

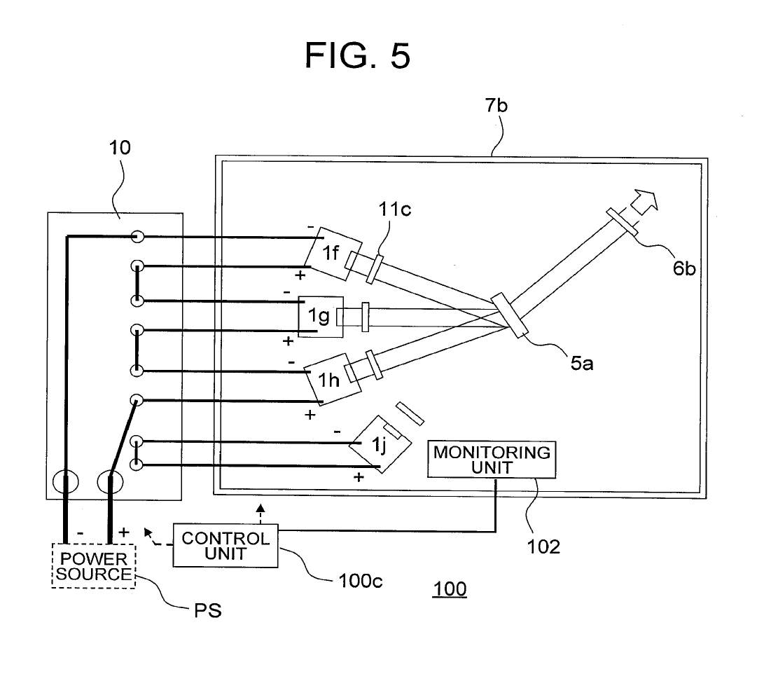

FIG. 5 is a schematic block diagram of a beam combining device according to a third embodiment of the present invention. As illustrated in FIG. 5, one optical path for a spare light source (spare LD package) may be provided inside the wavelength beam combining external resonator using the dispersive property, and the optical path may be switched only by the wiring switching from the power source when a failure (defect) occurs. In the embodiment described with reference to FIG. 5, when an LD device starts to be used, the LD packages 1f, 1g, and 1h each having an LD bar mounted thereon operate by being connected to one another in series on a wiring switching box 10 configured to conduct the connection and the disconnection of the LD packages to/from the power supply circuit, and form an external resonator in the same manner as in the second embodiment. That is, a common optical path is formed between a partially transmitting mirror 6b and the diffraction grating 5a, and separate optical paths are formed between the diffraction grating 5a and the LD packages 1f, 1g, and 1h because a diffraction angle differs depending on the wavelength due to the dispersive property of the diffraction grating 5a. Further, a spare (light source) LD package 1j is connected to the positive (+) terminal and the negative (−) terminal when started to be used in order to prevent a failure. The LD packages 1f, 1g, and 1h and the spare (light source) LD package 1j each include a cylindrical lens 11c.

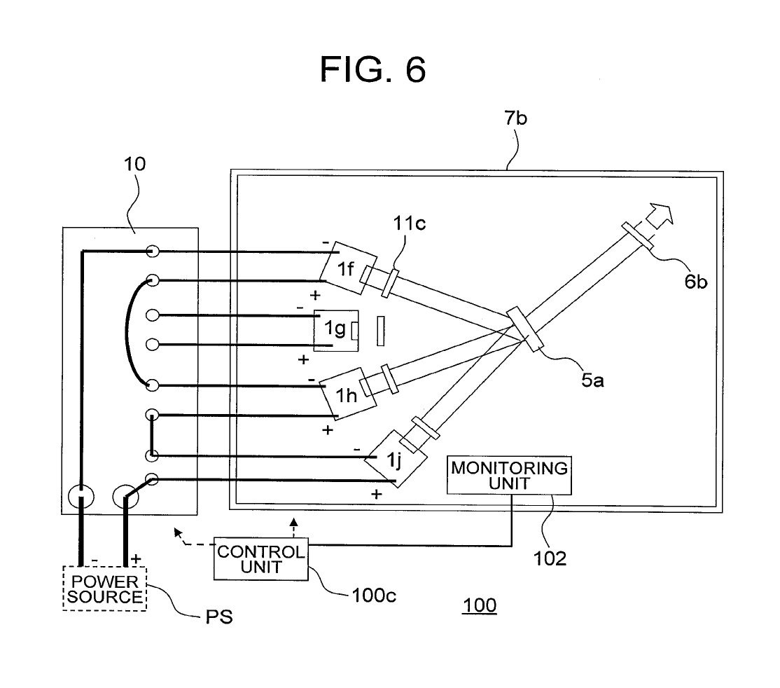

Next, FIG. 6 is an illustration of how the spare light source (LD package) 1j replaces the operation of the LD package 1g when the LD package 1g fails. In FIG. 6, the spare LD package 1j is configured so as to allow, in the diffraction grating 5a being entered by the light beams from the LD packages 1f to 1h, a beam to be superimposed on those beams after entering the diffraction grating 5a in the same position as that of another LD, and so as to have the beam having the same optical axis as that of another beam between the diffraction grating 5a and the partially transmitting mirror 6b.

Further, the spare LD package 1j has a gain sufficient to replace another LD within a wavelength range corresponding to the diffraction angle in an arrangement position illustrated in FIG. 6.

Further, in FIG. 6, the spare LD package 1j is arranged at an end, but may not necessarily be arranged at the end, and may be arranged between the LD packages or at both ends.

Further, the number of spare LD packages 1j does not need to be limited to one, and any number of spare LD packages 1j may be arranged depending on the redundancy to be required for the device.

Further, the operations relating to a capability of sharing the optical path between the diffraction grating 5a and the partially transmitting mirror 6b with another LD package, a capability of obtaining a predefined output and a predefined focusing property, and the like are adjusted in advance before the device starts to be used.

When the LD package 1g fails, the control unit 100c, which includes the monitoring unit 102 and the display unit configured to display the monitoring result, first detects and displays which LD package has failed. In a detection method for the failed LD package, as described in the second embodiment, the voltage of each LD package may be monitored, or the laser beam output from each LD package, the emission direction, the wavelength, and the like may be monitored. Further, only a light-receiving unit or a terminal for the monitoring may be provided, and may be connected to a fiber, a console, or a personal computer (PC) at a time of inspection. When it is detected and displayed which LD package has failed, as illustrated in FIG. 6, the operator uses the wiring switching box 10, which is arranged outside a casing 7b, to operate the device by stopping current supply to the LD package 1g (disconnecting the LD package 1g from the power supply circuit), connecting the spare LD package 1j to the power supply circuit, and switching the wirings so as to start the current supply.

In this case, the current and the voltage may be adjusted by a power source PS of the power supply circuit illustrated in FIG. 5, to thereby adjust the output from the LD package. Further, the power source PS can be used also as the power source for the drive motor of each drive unit.

In this embodiment, the wiring switching box 10 serving as a light source switching mechanism is provided outside the casing, and the wirings can be switched without the opening of the casing, which can prevent adverse influence of contamination or moisture from being exerted on optical elements and LD elements that are arranged within the casing. Further, the switching of the wirings and the monitoring can be conducted quickly, and hence it is possible to alleviate a load imposed on the operator in charge of maintenance. If possible, it is desired to automatically conduct any one of or both the detection of the failed LD package and the switching of the wirings.

That is, in the same manner as described in the above-mentioned embodiments, the control unit 100c determines the failed LD package based on the monitoring result of the state of the LD package obtained from the monitoring unit 102, outputs an open/close control signal to the electric switch SW configured to conduct the connection and disconnection of the wirings based on the determination result, the electric switch SW being provided on the wiring switching box 10 serving as a light source switching mechanism (including the movable unit and the drive unit) as exemplified in FIG. 16, and disconnects the failed LD package from the power supply circuit while connecting the spare LD package 1j to the power supply circuit instead. Further, the power source PS for the power supply circuit may be controlled to adjust the current and the voltage.

To briefly describe FIG. 16, the LD packages 1f to 1h and the spare LD package 1j are connected to one another in series, and a short circuit including the electric switch SW is provided to each LD package. In an initial stage corresponding to the state of FIG. 5, the electric switch SW of the short circuit of the spare LD package 1j is turned on (connected in an energized state), while the electric switches SW of the short circuits of the LD packages 1f, 1g, and 1h are turned off (disconnected in a state that inhibits energization) so that the LD packages 1f, 1g, and 1h operate, and hence the device effects the function. When the LD package 1g fails as illustrated in, for example, FIG. 6, the electric switch SW of the short circuit provided to the LD package 1g is changed from an off state to an on state, while the electric switch SW of the short circuit provided to the spare LD package 1j is changed from an on state to an off state conversely, to thereby operate the LD packages 1f and 1h and the spare LD package 1j. The configuration of the switching circuit is merely an example, and may be configured suitably for the purpose.

Hitherto, automatic switching of a current is easy when the current is small, but as in this embodiment, there is a case where it is difficult to automate the switching of a large current on the order of equal to or larger than several amperes with the device being increased in size, and hence the wiring switching box 10 may be provided outside the casing to provide a mechanism for manual switching. That is, the effects of the present invention are achieved to a large extent when the current that energizes the light source is a current exceeding one ampere.

In this embodiment, the wavelength beam combining external oscillator is formed by separately providing an optical path to a spare package, to thereby be able to continue a normal operation at the time of failure only by the switching of the wirings without providing the moving mechanism or the like unlike in the second embodiment. By omitting the moving mechanism, it is possible to achieve the downsizing of the device and the reduction of the time required for the replacement.

### Fourth Embodiment

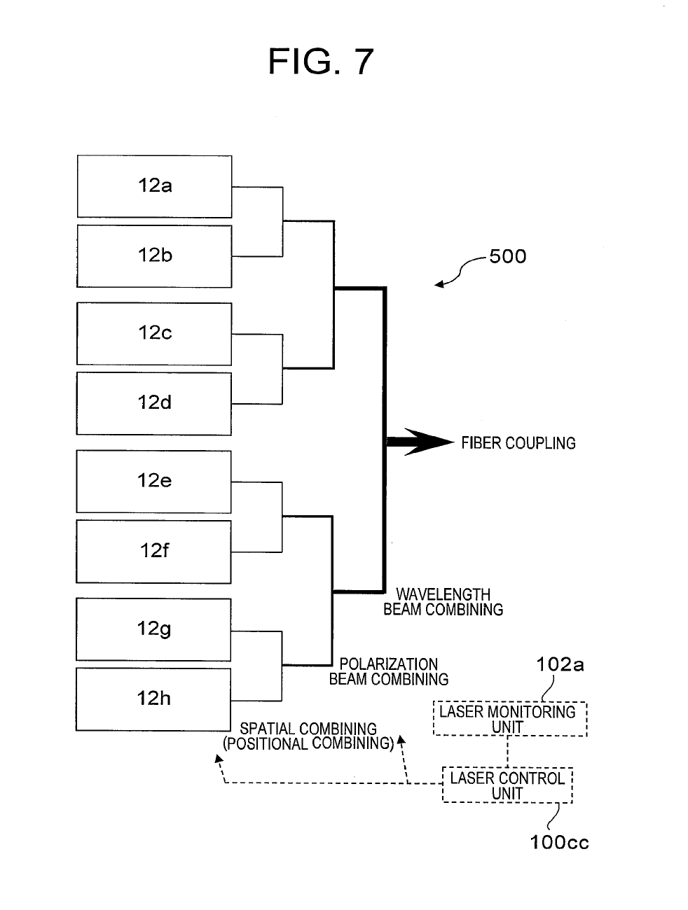

FIG. 7 is a schematic block diagram of a beam combining device according to a fourth embodiment of the present invention. In FIG. 7, each of laser modules 12a to 12h is a wavelength beam combining external resonator including the spare LD package described in, for example, the third embodiment 3d. That is, the laser modules 12a to 12h each include the LD packages 1f to 1h, the spare LD package 1j, the cylindrical lens 11c, the diffraction grating 5a, the partially transmitting mirror 6b, the casing 7b, the wiring switching box 10, the monitoring unit 102, and the control unit 100c that are illustrated in, for example, FIG. 5. In this embodiment, the adjacent laser modules, namely, 12a and 12b, 12c and 12d, 12e and 12f, and 12g and 12h, are respectively subjected to the spatial combining (positional combining), and a total of eight beams emitted from the respective modules become four beams.

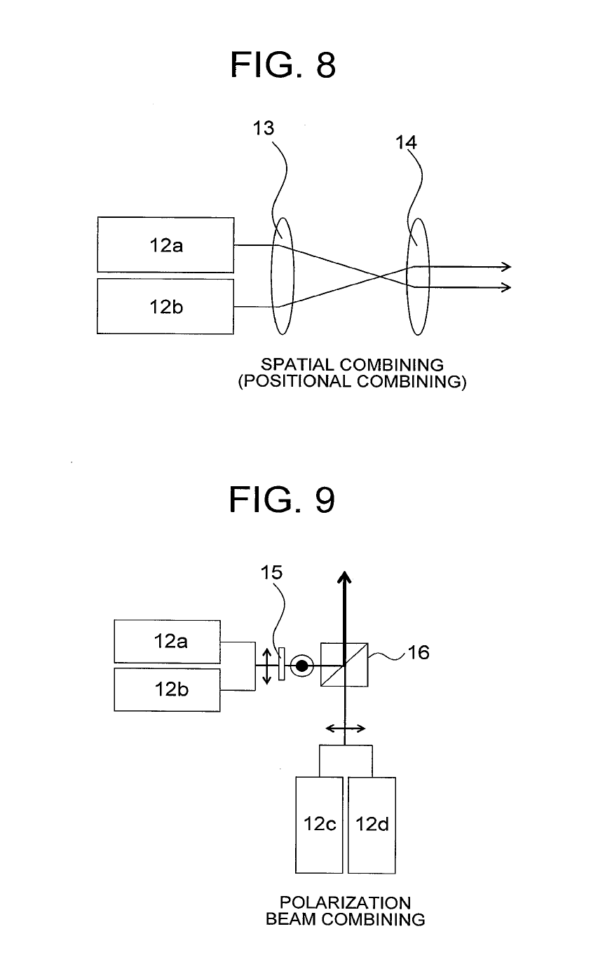

The spatial combining (positional combining) is briefly described with reference to FIG. 8. In FIG. 8, the laser beams generated from the laser modules 12a and 12b are condensed by a first cylindrical lens 13. Then, the laser beams are collimated by a second cylindrical lens 14 arranged after the focusing point is passed, and are caused to have a spacing narrower than when entering the first cylindrical lens 13. The laser beams having the spacing thus made narrower have the focusing property improved collectively as two beams subjected to the spatial combining (positional combining) compared to immediately after the laser beams are emitted from the laser modules 12a and 12b, and although not superimposed into one beam, can have a size and a divergence angle so as to be able to enter the fiber when a fiber diameter and a numerical aperture (NA) of the fiber are selected appropriately, which can be said to have successfully been substantially combined to each other. Further, the method illustrated in FIG. 8 is merely an example, and a variety of other optical systems are conceivable. Further, the case of combining two beams is described here, but the number of beams to be subjected to the spatial combining (positional combining) may be increased depending on the focusing property of the beams emitted from the laser modules as long as the focusing property that allows the beams to enter the fiber can be maintained.

Next, as illustrated in FIG. 7, the beams subjected to the spatial combining (positional combining) are subjected to the polarization beam combining, to thereby become two beams in total. The polarization beam combining is described with reference to FIG. 9. In FIG. 9, the laser beams generated from the laser modules 12a and 12b have a polarization direction rotated by 90 degrees by a polarization rotating element 15, e.g., a wave plate or a polarization rotator, as illustrated in FIG. 9. As a result, the polarization direction of the beams generated from the laser modules 12a and 12b becomes different by 90 degrees from the polarization direction of the beams generated from the laser modules 12c and 12d, and the beams are superimposed into one beam by a polarization element 16.

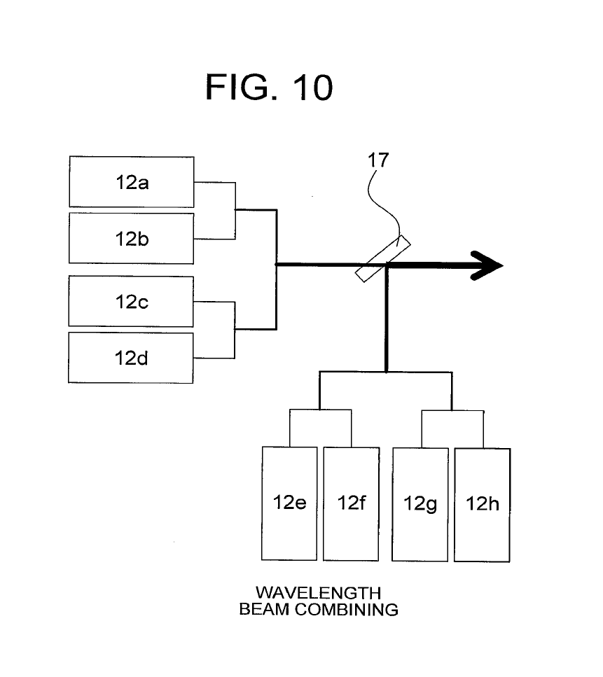

Next, the beams are further combined to one beam by the wavelength beam combining as illustrated in FIG. 7. The wavelength beam combining is described with reference to FIG. 10. The beams from the laser modules 12a to 12d and the beams from the laser modules 12e to 12h are combined by a wavelength beam combining mirror 17, to thereby be combined into one beam. The laser modules 12a to 12d and the laser modules 12e to 12h need to use laser diodes having different wavelengths. Further, the number of beams to be subjected to the wavelength beam combining is not limited to two, and may be any number equal to or larger than three, but it is necessary to provide laser diodes having different specifications in order to change the number of beams. Finally, the beams are subjected to the fiber combining as illustrated in FIG. 7 to be used.

In the beam combining device having the above-mentioned configuration, a failure does not always occur in each one of the LD packages (LDs) within one laser module as illustrated in FIG. 5 and FIG. 6, and two or more LD packages may fail within one laser module. Further, there may be a case where a failure occurs due to a broken wire, contamination, or the like to completely stop the operation of one laser module (all the LD packages within one laser module may fail or become unable to output a beam).

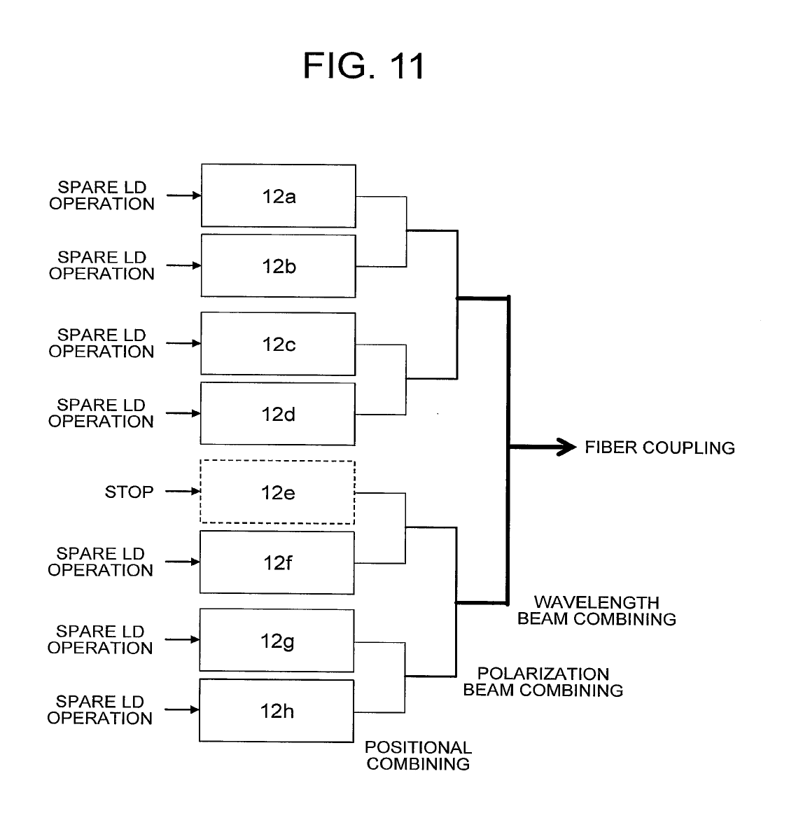

FIG. 11 is an illustration of an operation of the beam combining device according to the present invention when the laser module 12e cannot operate. As illustrated in FIG. 11, when the laser module 12e cannot operate due to a failure, the laser module 12e stops operating. At this time, as an emergency measure, all the spare LD packages mounted to the other laser modules are operated, to thereby compensate the reduction in the output due to the stoppage of the laser module 12e and continue the operation until the maintenance is conducted. Therefore, a plurality of spare LD packages may be provided to each laser module, or there may be a laser module provided with no spare LD package. Further, as an emergency measure, the operation may be continued by increasing the current instead of operating the spare LD package. Further, when two or more LD packages fail within one laser module and only a part of the spare LD packages needs to be operated, it is not necessary to operate all the spare LD packages, and the operation may be continued only by operating as many spare LD packages as required.

With the beam combining device configured in the above-mentioned manner, it is not necessary to provide one separate laser module as a spare, and it is possible to improve the redundancy of the entire beam combining device, and to continue the operation while maintaining a desired output even when one laser module stops. Further, the cost of providing one spare LD package to each laser module can be reduced when the number of LD packages included in one laser module is exceeded by the number of beams combined after being emitted from the laser modules.

In order to increase the number of beams to be combined, there is no other way than to increase the number of beams to be subjected to the spatial combining (positional combining) or the wavelength beam combining. When the number of beams to be subjected to the spatial combining (positional combining) is increased, the focusing property of the beams within the entire device is degraded. When the number of beams to be subjected to the wavelength beam combining is to be increased, it is necessary to increase the wavelength, which leads to an increase in cost and makes the maintenance more difficult. As understood from the above description, there is a limitation on the number of beams to be combined after being emitted from the laser modules, and in order to increase the output, it is more advantageous to increase the number of beams to be subjected to the wavelength beam combining through use of a diffraction grating or a dispersive optical element that serves as a beam combining element within the module. In the case of the wavelength beam combining device using the dispersive optical element, the effects of the present invention are achieved to a large extent.

Compared to a case of providing a spare laser module relating to a method of ensuring the redundancy, which is different from the present invention, it is possible to form the device with a smaller number of parts and to lower an occurrence probability of a failure. Further, it is possible to downsize the device.

Further, the possibility of handling various failures is expanded. For example, when one spare laser module is provided, it is conceivable that the spare laser module can no longer operate normally due to a failure, but as in this embodiment, when the output reduction of one laser module is compensated by another laser module as configured in this embodiment, it is possible to cover the failure even when one laser module is broken. Further, it is also possible to reduce the number of LD packages to be required to ensure the redundancy.

Further, as representatively illustrated by the broken lines in FIG. 7 (the same applies to the subsequent embodiments), there may be provided: a laser monitoring unit 102a configured to centrally input the monitoring results from the respective monitoring units 102 of all the laser modules within the beam combining device, and to monitor the states for detecting a defect (failure) in the respective laser modules and the respective LD packages within each laser module; and a laser control unit 100cc configured to determine a failed laser module or a failed LD package based on the monitoring results of the states of the laser modules and the LD packages obtained from the laser monitoring unit 102a, and to send, for example, to the control unit 100c of the corresponding laser module, the control signal for causing the control unit 100c to output the open/close control signal for controlling the opening and closing of an electric switch (not shown) provided on the wiring switching box 10 based on the determination result.

Further, in this case, as described later, in order to compensate the output from the failed LD package, the laser control unit 100cc may be configured to control the control unit 100c of the corresponding laser module to conduct such control as to increase the output from a normal LD package, to thereby conduct such control as to increase the current supplied to the LD of the LD package controlled by the control unit 100c.

Further, the laser control unit 100cc may be configured to directly conduct the control (including output adjustment and wiring switching control through the wiring switching box 10) of all the laser modules and the LD packages without the intermediation of the control units 100c of the respective laser modules.

Further, the configuration of each laser module is not limited to the configuration according to the third embodiment, and may be the configuration including the spare LD package as described in another embodiment.

### Fifth Embodiment

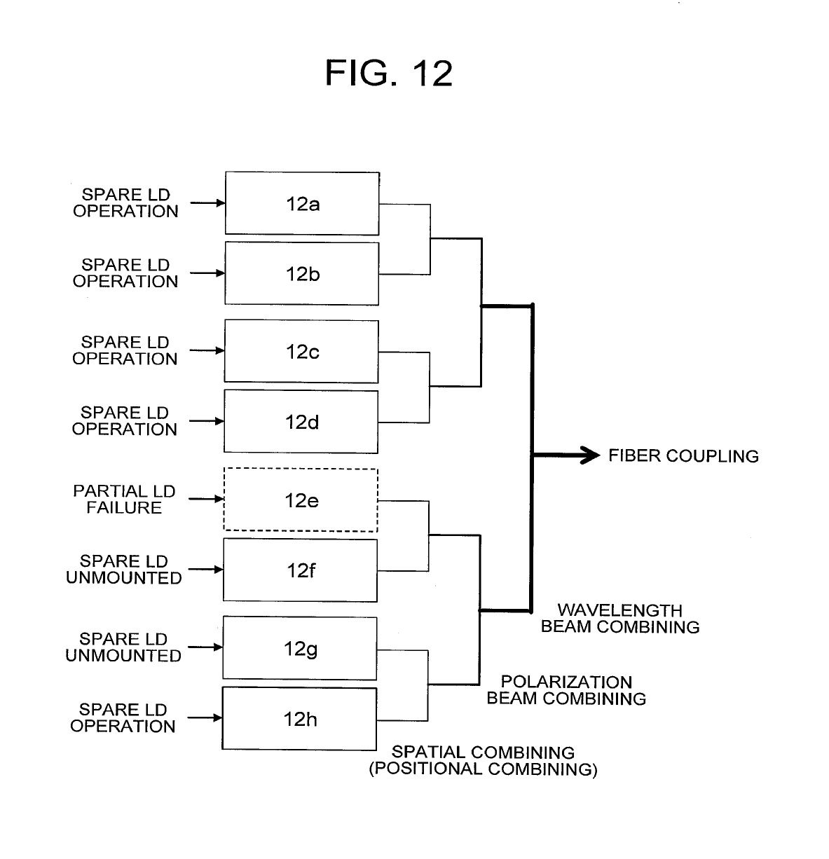

FIG. 12 is a schematic block diagram of a beam combining device according to a fifth embodiment of the present invention. The beam combining device of FIG. 12 includes wavelength beam combining external resonators having a dispersive property within a plurality of laser modules in the same manner as the beam combining device according to the fourth embodiment, and the wavelength beam combining external resonators generate a laser beam obtained by subjecting the beams to the combining through the space (position), polarization, and wavelength to combine the beams into one beam. Some beam combining devices have almost no defect in the entire laser module, and a defect occurs almost in the case of a single LD package, which may make it unnecessary to prepare for the case where the laser module stops operating. In FIG. 12, the laser modules 12f and 12g are not provided with a spare LD package.

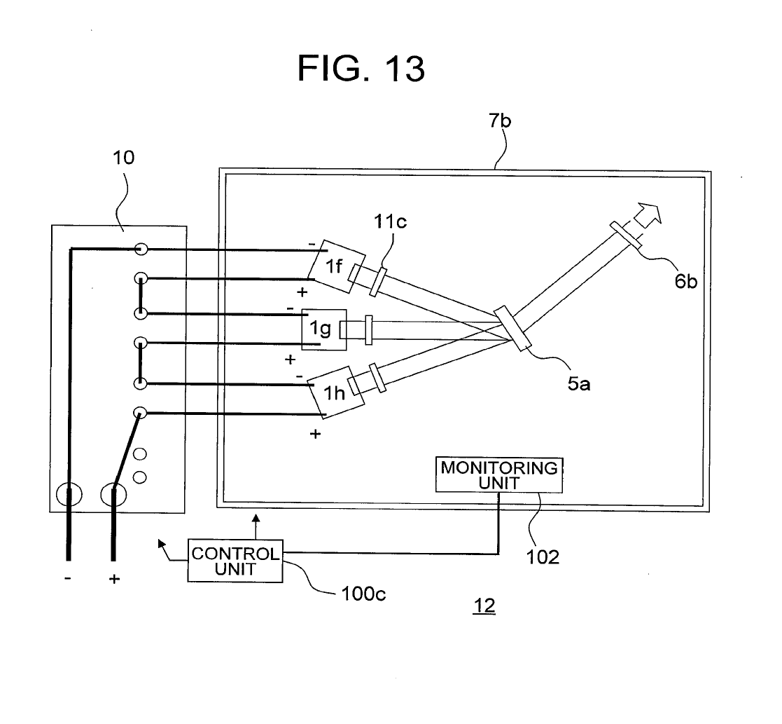

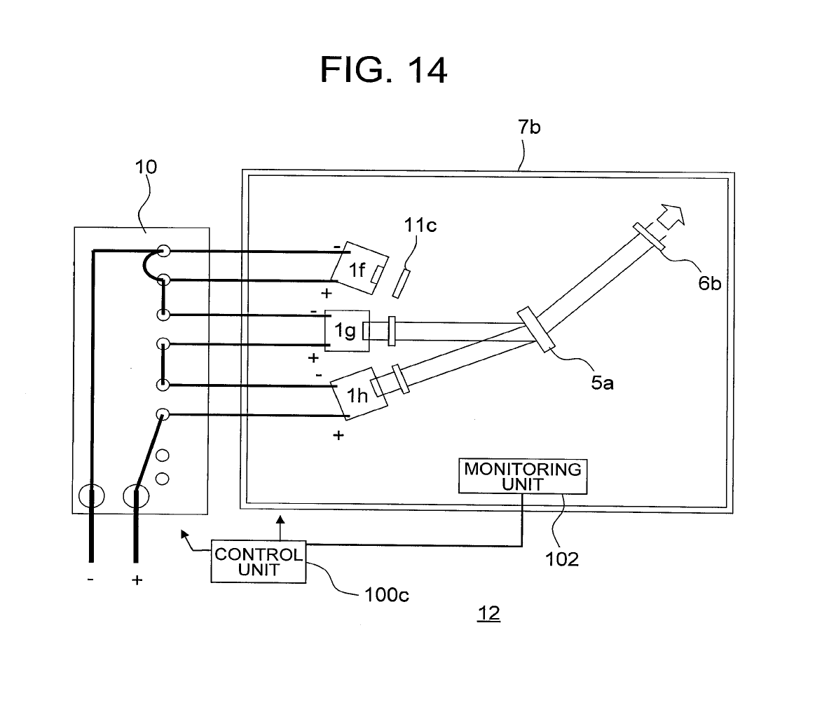

FIG. 13 is an illustration of a laser module provided with no spare LD package. Further, FIG. 14 is an illustration of how the wirings are changed when one of the LD packages illustrated in FIG. 13 fails. In FIG. 13, no spare LD package is provided inside the laser module. In regard to the wirings, in the same manner as in FIG. 5 and FIG. 6, the wiring switching box 10 is provided so that the wirings can be switched outside the casing 7b so as to be able to short-circuit the LD package whichever of the LD packages causes a defect. At the time of failure, as illustrated in FIG. 14, the wirings are short-circuited between the two positive and negative terminals of the failed LD package 1f, to stop the operation. The stoppage of the operation of the LD package 1f lowers the output from the entire laser module.

The above-mentioned wirings are equivalent to those of the LD package 1f disconnected from the power supply circuit. Further, in this case, the LD package 1f may be wired so as to be disconnected from the power supply circuit.

When the LD package stops operating, as illustrated in FIG. 12, not only the spare laser module within the same laser module but also the spare laser module arranged inside another laser module operate, which makes it unnecessary to provide a spare LD package to every laser module, and it is possible to continue the operation until the maintenance is conducted. Further, the number of spare LD packages does not need to be limited to one per module, and may be increased as the need arises. Even with the laser module having one spare LD package, it is possible to omit the optical element, the casing, and the like. With such a configuration, the number of parts is small, and hence it is possible to downsize the device. Further, it is possible to lower the occurrence probability of a failure.

### Sixth Embodiment

Further, when the device configured so that an operation current value of the LD of the LD package has a limit of, for example, 60 A has a characteristic that the output increases depending on the current within a current range equal to or smaller than 60 A, the device may be operated in the following manner. That is, the device is kept operating with 40 A or 50 A at all times, and at a time of failure in the LD package, only the failed LD package is disconnected from the power supply circuit by the wiring switching, the current value is increased to, for example, 55 A or the like to ensure a required output, and the operation is continued until the maintenance can be conducted.

In this case, any spare LD package does not need to be mounted when the total number of LD packages is large enough to cover failures of several LD packages by increasing the current and when the possibility that one laser module may stop suddenly is extremely low. Further, the number of spare LD packages may be greatly reduced. That is, the number of spare LD packages can be reduced depending on a failure probability (frequency) and a severity level of a possible failure. When the redundancy is ensured with such a method, the number of LD packages to be required can be reduced, and the occurrence probability of a failure can be lowered. Further, it is possible to downsize the device.

### Seventh Embodiment

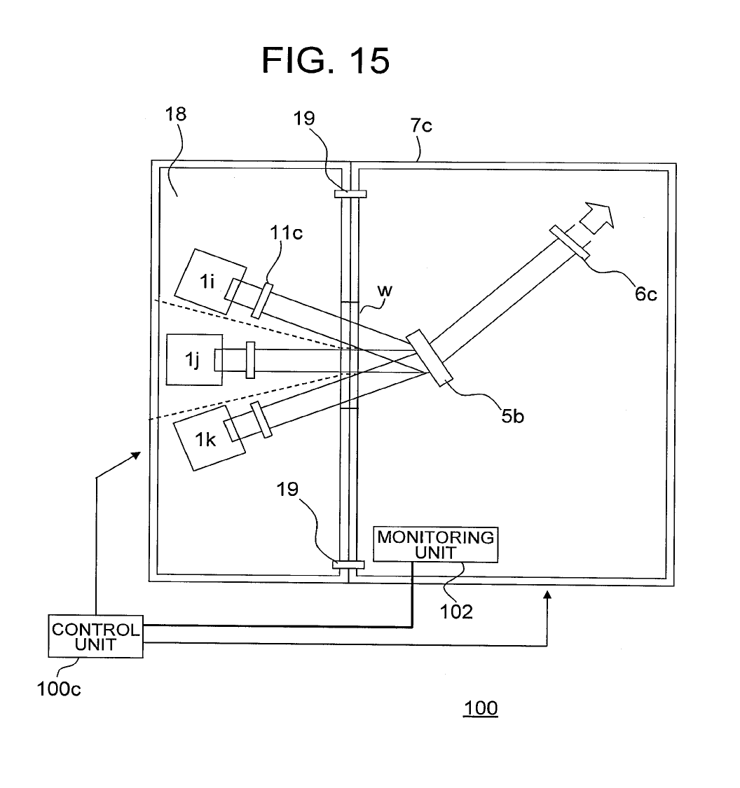

FIG. 15 is a schematic block diagram of a beam combining device according to a seventh embodiment of the present invention. As illustrated in FIG. 15, a casing 18 and a casing 7c may be separately provided. In the casing 18, the LD packages 1i, 1j, and 1k that may cause the failure and optical parts including the cylindrical lenses 11c around the LD packages are arranged. In the casing 7c, a diffraction grating 5b, the partially transmitting mirror 6c, and other such optical elements are arranged. In this case, instead of arranging the LD packages one by one by being adjusted so that all of the LD packages finally operate normally, the adjustment may be conducted only with the casing 18 in a different place, and at the site, positioning members 19 each exhibiting positional accuracy in abutment faces, pins, and the like may be provided, and the casing 7c and the casing 18 may be arranged with positional accuracy equal to or higher than predefined accuracy. Further, the casing 18 and the casing 7c may include windows W so as not to be internally influenced by contamination or moisture even when being removed. Further, the windows M may be covered only when removed so that a normal operation may not be influenced by the windows. Further, in order to adjust the casing 18, another casing 7c serving as a reference may be provided so as to allow the adjustment in another place. Also in FIG. 15, the monitoring unit 102 and the control unit 100c are provided, but as illustrated in FIG. 15, those may be provided to the casing 7c, provided to the casing 18, or separately provided to both.

In this manner, the casing of the LD packages and the optical parts is split, to thereby allow the LD package to be easily replaced. Further, in FIG. 15, there may be provided an adjustment mechanism configured to conduct fine motion adjustment for a positional relationship between the casing 18 and the casing 7c. Further, the adjustment mechanism may be provided to a part or all of the diffraction grating 5b, the partially reflective mirror 6c, and other such part that form the casing 7c to conduct adjustment control from the control unit 100c. It is desired that the adjustment mechanism be set as a mechanism that allows fine motion without opening the casing in terms of the prevention of contamination or moisture.

Further, in FIG. 15, all the LD packages are stored in one casing 18, but as indicated by the broken lines, a part of the LD packages may be contained in another casing, and only the casing of the part of the LD packages may be replaced. Further, another casing 18 may be provided as a replacement part, and only the casing 18 may be replaced at the time of failure.

With such a configuration, at the time of replacement, the possibility that the LD package may be influenced by contamination or moisture can be lowered, and hence it is possible to increase the life of the LD package.

The LD packages 1i, 1j, and 1k may include a spare LD package.

### Eighth Embodiment

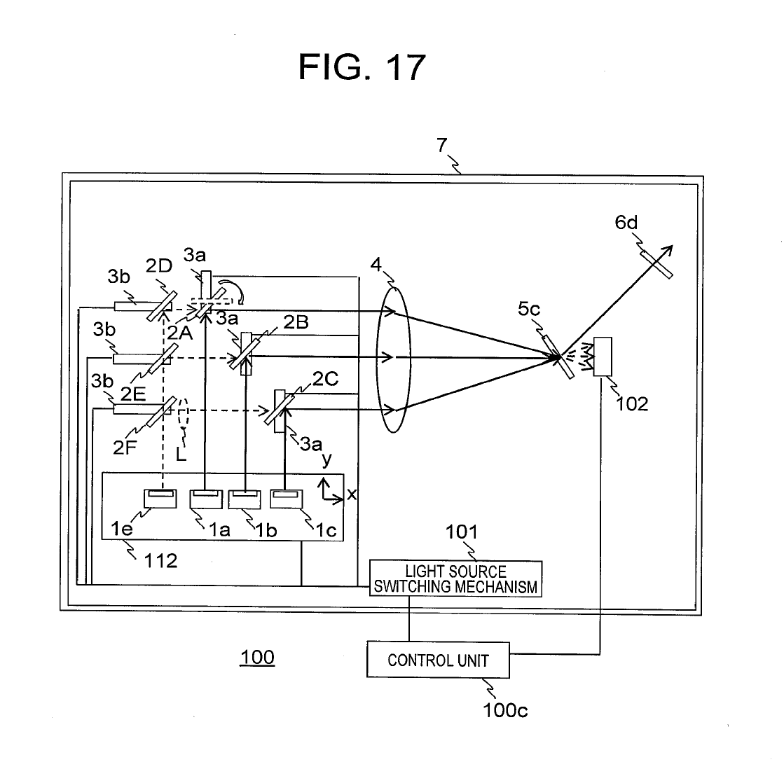

FIG. 17 is a schematic block diagram of a beam combining device according to an eighth embodiment of the present invention. In this embodiment, a configuration for the switching between a failed LD package (light source) and a spare LD package (spare light source) is described in relation to the first embodiment. The LD package 1e is a spare light source, and the LD packages 1a, 1b, and 1c are a plurality of light sources. In FIG. 1, the LD packages 1a, 1b, and 1c, the folding mirrors 2A to 2F, the cylindrical lens 4, a dispersive optical element 5c serving as the beam combining element, and the output coupling element 6d serving as an output optical element form an external resonator.

The light beams emitted from the LD packages 1a, 1b, and 1c are combined into one beam between the output coupling element 6d and the dispersive optical element 5c, and extracted from the output coupling element 6d. Further, a part of the beams having entered the output coupling element 6d is returned to the LD packages 1a, 1b, and 1c via the dispersive optical element 5c. In this case, the part of the light beams from the LD packages 1a, 1b, and 1c enter the monitoring unit 102, and the lowering of the output can be detected when the lowering is determined based on, for example, a comparison with the intensity of the output signal at a normal time. At this time, the control unit 100c operates the light source switching mechanism 101 depending on the failed site based on the detection result of the failed site in the LD package 1a, 1b, or 1c obtained from the monitoring unit 102, so that an optical path connecting between the failed LD package and the dispersive optical element 5c is brought to a stopped state, and that an optical path connecting between the spare LD package 1e and the dispersive optical element 5c is brought to an operating state.

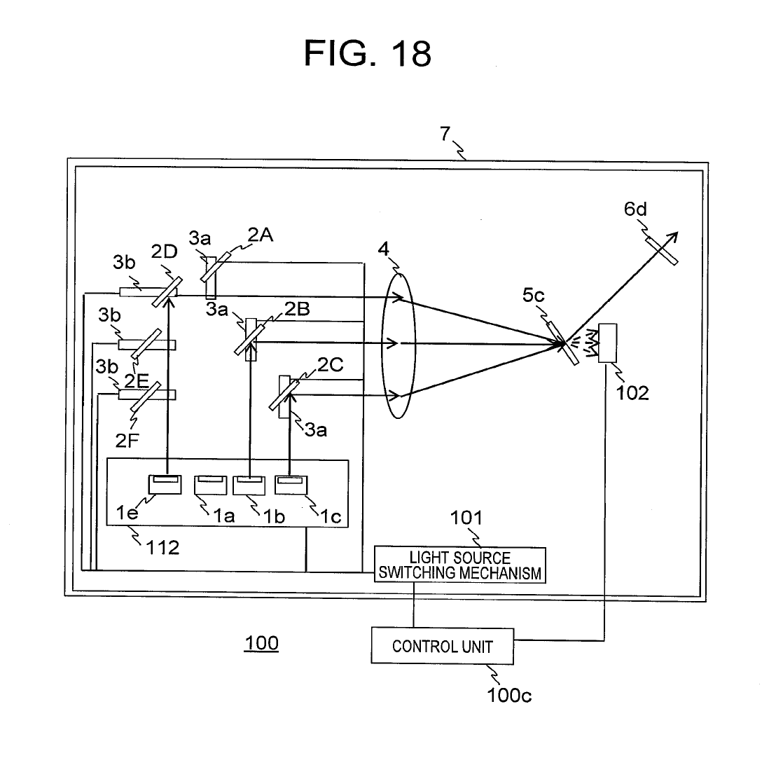

For example, when the LD package 1a fails, the folding mirrors 2A, 2E, and 2F are moved as illustrated in FIG. 18, to thereby enable the spare LD package 1e to replace the operation of the LD package 1a.

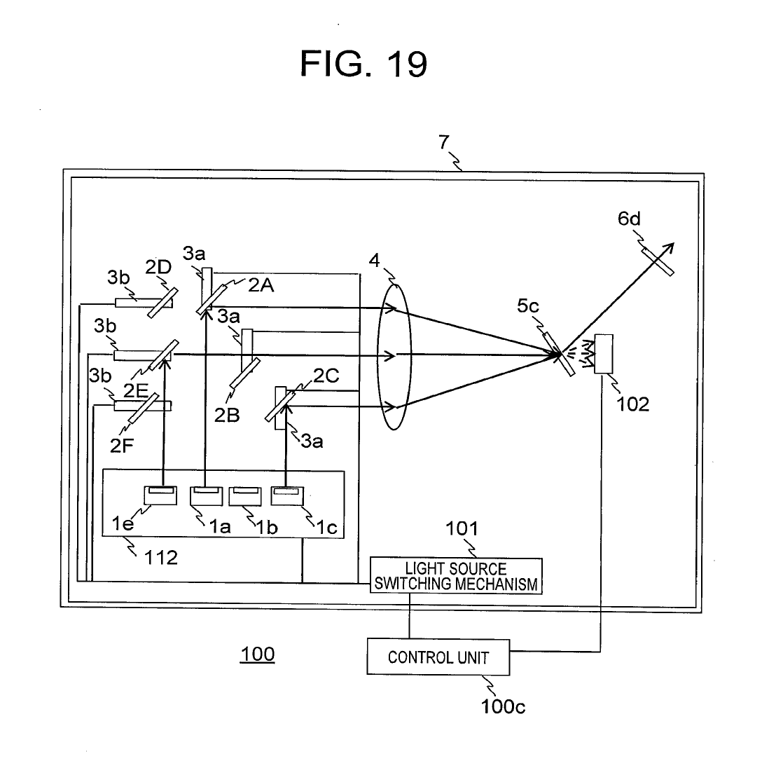

Further, when the LD package 1b fails, the folding mirrors 2B and 2F are moved as illustrated in FIG. 19, to thereby enable the spare LD package 1e to replace the operation of the LD package 1b.

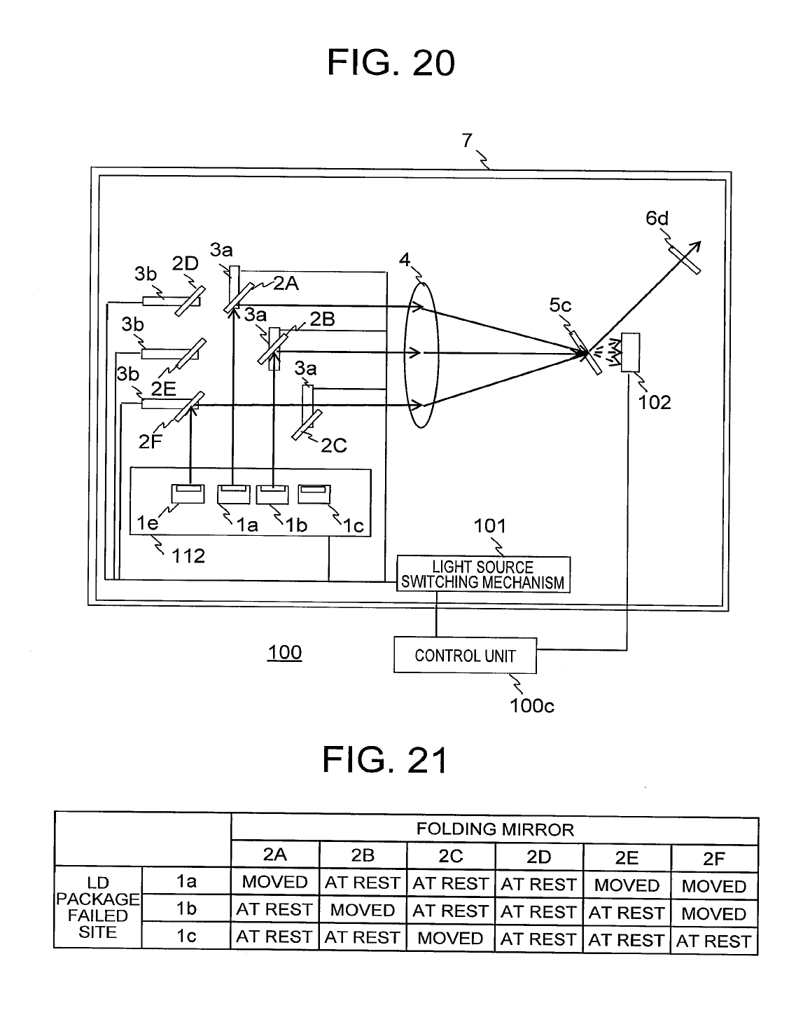

Further, when the LD package 1c fails, the folding mirror 2C are moved as illustrated in FIG. 20, to thereby enable the spare LD package 1e to replace the operation of the LD package 1c.

The spare LD package 1e is adjusted in advance by adjusting the folding mirrors 2D, 2E, and 2F under a state in which the folding mirrors 2A, 2B, and 2C have been removed, so that the wavelength beam combining external resonator can operate with any of the folding mirrors 2D, 2E, and 2F. FIG. 21 is a table for collectively showing the folding mirrors to be moved and the folding mirrors to be at rest for a failure in each LD package.

Although not shown in detail, the components may be arranged so that a distance between the spare LD package 1e and the dispersive optical element 5c and a distance between the LD packages 1a, 1b, and 1c and the dispersive optical element 5c are the same, and, for example, a lens (exemplified by the broken line in FIG. 17) or the like may be provided within the optical path so that an image in the position of the spare LD package 1e is transferred onto a position overlapping with the optical path from the LD packages 1a, 1b, and 1c. Further, for example, as illustrated in FIG. 5, FIG. 6, FIG. 16, and the like, a circuit configured to disconnect the circuit of the failed LD package from the power supply circuit to conduct the switching so as to supply power to the spare LD package 1e may be provided as the need arises. Further, a method of removing the folding mirror from the optical path is not limited to the movement as long as the folding mirror does not act on the optical path, and the same effects are obtained even when rotation (indicated by the broken line in the folding mirror 2A of FIG. 17) or a combination of the movement and the rotation is employed.

The folding mirrors 2A to 2F are each configured to move on rails 3a and 3b or rotate about, for example, the center of the folding mirror by a drive motor (not shown).

Further, by providing the LD packages 1a, 1b, and 1c and the spare LD package 1e on a movement substrate 112 illustrated in FIG. 17 within an xy plane so as to be movable by a drive motor (not shown), it is possible to replace the position of the LD package by the spare LD package to support the failed LD package.

In the first embodiment described above (FIG. 1 and FIG. 2):

the LD packages 1a to 1d form the light sources;

the LD package 1e forms the spare light source;

the diffraction grating 5 forms the beam combining element;

the folding mirror 2, the cylindrical lens 4, the diffraction grating 5, and the partially transmitting mirror 6 form a beam combining optical system;

the monitoring unit 102 forms the monitoring unit; and

the light source switching mechanisms 101 and 111 and the control unit 100c form a power source switching unit.

Further, the mechanism for moving the folding mirror 2 onto the rail 3, the electric switch SW having the mechanism for conducting the adjustment and on/off control of the power supply from the power supply circuit to the respective LD packages 1a to 1e, which is illustrated in, for example, FIG. 16, and the like form the movable unit of the light source switching mechanism 101. Further, the drive motor for driving the movable unit, the power supply circuit to the LD package, the power source for those, and the like form the drive unit of the light source switching mechanism 101.

In the second embodiment described above (FIG. 3 and FIG. 4):

the LD packages 1f, 1 g, and 1h form the light sources;

the LD package 1i forms the spare light source;

the diffraction grating 5a forms the beam combining element;

the cylindrical lens 11, the movable mirrors 2a and 2b, the diffraction grating 5a, and the partially transmitting mirror 6a form the beam combining optical system;

the monitoring unit 102 forms the monitoring unit; and

the light source switching mechanism 101 and the control unit 100c form the power source switching unit.

Further, the movable support portions configured to movably support the LD package 1i, the cylindrical lens 11b, and the movable mirrors 2a and 2b, the electric switch SW having the mechanism for conducting the adjustment and on/off control of the power supply from the power supply circuit to the LD packages, which is illustrated in, for example, FIG. 16, and the like form the movable unit of the light source switching mechanism 101. Further, the drive motor for driving the movable unit for those, the power supply circuit to the LD package, the power source for those, and the like form the drive unit of the light source switching mechanism 101.

In the third embodiment described above (FIG. 5 and FIG. 6):

the LD packages 1f, 1g, and 1h form the light sources;

the LD package 1j forms the spare light source;

the diffraction grating 5a forms the beam combining element;

the cylindrical lens 11c, the diffraction grating 5a, and the partially transmitting mirror 6b form the beam combining optical system;

the monitoring unit 102 forms the monitoring unit;

the wiring switching box 10 forms the wiring switching box;

the casing 7b forms the casing; and

the control unit 100c (light source switching mechanism 101) forms the power source switching unit.

Further, when the light source is automatically controlled, the electric switch SW having the mechanism for conducting the adjustment and on/off control of the power supply from the power supply circuit to the LD package, which is illustrated in, for example, FIG. 16, and the like form the movable unit of the light source switching mechanism 101. Further, the power supply circuit to the LD package, the power source therefor, and the like form the drive unit of the light source switching mechanism 101.

In the fourth to sixth embodiments described above (FIG. 7 and FIG. 14):

the laser modules 12a to 12h form the laser modules;

a spatial combining (positional combining) unit, a polarization beam combining unit, a wavelength beam combining unit, and a fiber coupling unit form a module beam combining optical system 500;

the laser monitoring unit 102a forms a laser monitoring unit; and

the laser control unit 100cc forms a laser control unit.

The configuration within each laser module is the same as the configuration of another embodiment.

In the seventh embodiment described above (FIG. 15):

the LD packages 1i, 1j, and 1k form the light sources and the spare light sources;

the diffraction grating 5b forms the beam combining element;

the cylindrical lens 11c, the diffraction grating 5b, and the partially transmitting mirror 6c form the beam combining optical system;

the casing 7c forms a main casing;

the casing 18 (including each of the divided casings) forms sub-casings; and

the positioning members 19 form positioning units.

In the eighth embodiment described above (FIG. 17 to FIG. 21):

the LD packages 1a to 1c form the light sources;

the LD package 1e forms the spare light source;

the folding mirrors 2A to 2E form the optical element;

the dispersive optical element 5c forms the beam combining element;

the output coupling element 6d forms the output optical element;

the folding mirrors 2A to 2E, the cylindrical lens 4, the dispersive optical element 5c, and the output coupling element 6d form the beam combining optical system;

the monitoring unit 102 forms the monitoring unit; and

the light source switching mechanism 101 and the control unit 100c form the power source switching unit.

Further, the mechanism for moving the folding mirrors 2A to 2E onto the rails 3a and 3b, the mechanism for moving the LD packages 1a to 1c onto the movement substrate 112, the electric switch SW having the mechanism for conducting the adjustment and on/off control of the power supply from the power supply circuit to the respective LD packages 1a to 1c, and 1e, which is illustrated in, for example, FIG. 16, and the like form the movable unit of the light source switching mechanism 101. Further, each drive motor for driving the movable unit, the power supply circuit to the LD package, the power source therefor, and the like form the drive unit of the light source switching mechanism 101.

Further, the present invention is not limited to the respective embodiments described above, and includes all possible combinations of those embodiments. Further, the light source switching of the beam combining device according to each of the embodiments may be conducted manually, or may be conducted automatically by a control unit or the like.

### INDUSTRIAL APPLICABILITY

The configuration of the beam combining device according to the present invention can be applied to beam light sources in different kinds of fields.

### REFERENCE SIGNS LIST

1a-1j LD package,
2, 2A-2F folding mirror
2a, 2b movable mirror,
3, 3a, 3b rail
4, 11, 11b, 11c cylindrical lens,
5, 5a, 5b diffraction grating
5c dispersive optical element,
6, 6a, 6b, 6c partially transmitting mirror, 6d output coupling element
7, 7a, 7b, 7c,
18 casing,
10 wiring switching box
12a-12h laser module,
13 first cylindrical lens
14 second cylindrical lens,
15 polarization rotating element,
16 polarization element
17 wavelength beam combining mirror,
19 positioning member,
100 beam combining device
100c control unit,
100cc laser control unit,
101, 111 light source switching mechanism,
102 monitoring unit,
102a laser monitoring unit,
movable unit 1011,
drive unit 1012
SW electric switch,
W window

1-12. (canceled)

13. A beam combining device, comprising:
a plurality of laser modules each configured to have beams from a plurality of light sources combined into one beam by a beam combining optical system comprising a beam combining element;
a module beam combining optical system configured to combine beams from the plurality of laser modules, and to output the combined beams;
a laser monitoring unit configured to monitor wavelengths of the beams from the respective laser modules or a direction of leakage light from the beam combining element, to detect output reduction of the laser module; and
a laser control unit configured to increase, when the output reduction of the laser module is detected, an output of one or a plurality of the laser modules other than the laser module exhibiting the output reduction.

14. The beam combining device according to claim 13, wherein the plurality of laser modules comprise one or a plurality of laser modules having a spare light source mounted thereon.

15. The beam combining device according to claim 13, wherein the beam combining element comprises a dispersive optical element.

16. The beam combining device according to claim 14, wherein the beam combining element comprises a dispersive optical element.

17. The beam combining device according to claim 15, wherein:
the beam combining optical system comprises the dispersive optical element and an output coupling element;
the dispersive optical element is configured to receive beams from the respective light sources and the spare light source, and send the beams to the output coupling element; and
the output coupling element is configured to receive a beam from the dispersive optical element, output a part of the beam, and return a part of the beam to the respective light sources and the spare light source via the dispersive optical element.

18. The beam combining device according to claim 16, wherein:
the beam combining optical system comprises the dispersive optical element and an output coupling element;
the dispersive optical element is configured to receive beams from the respective light sources and the spare light source, and send the beams to the output coupling element; and
the output coupling element is configured to receive a beam from the dispersive optical element, output a part of the beam, and return a part of the beam to the respective light sources and the spare light source via the dispersive optical element.

19. An output recovery method for a beam combining device,
the beam combining device being configured to cause beams from a plurality of light sources and one or a plurality of spare light sources to enter a beam combining optical system, and to be combined and output after passing through a beam combining element,
the output recovery method comprising:
detecting a failure in the plurality of light sources by monitoring wavelengths of the plurality of light sources or a direction of leakage light from the beam combining element; and
moving at least a part of the respective light sources, the spare light source, and the beam combining optical system, causing a beam to enter the beam combining optical system from the spare light source instead of a beam from the failed light source, and causing the beam to be combined to beams from the plurality of light sources on an optical path after the beam combining element.

20. An output recovery method for a beam combining device,
the beam combining device being configured to cause a module beam combining optical system to combine beams from a plurality of laser modules each configured to have beams from a plurality of light sources combined into one beam by a beam combining optical system comprising a beam combining element, and to output the combined beams,
the output recovery method comprising:
detecting output reduction of the laser module by monitoring a wavelength of the laser module or a direction of leakage light from the beam combining element; and
increasing an output of one or a plurality of the laser modules other than the laser module exhibiting output reduction by increasing an output from a power source or switching to a spare light source.
